(19) United States
(12) Patent Application Publication
(10) Pub. No.: US 2015/0124077 A1
(43) Pub. Date: May 7, 2015

(54) CHARGED PARTICLE BEAM ADJUSTMENT ASSISTANCE DEVICE AND METHOD

(71) Applicant: Hitachi High-Technologies Corporation, Minato-ku, Tokyo (JP)

(72) Inventors: Naohiko Fukaya, Tokyo (JP); Kenji Kitagawa, Tokyo (JP); Masakazu Yagi, Tokyo (JP); Yukie Hiratsuka, Tokyo (JP); Wataru Kotake, Tokyo (JP)

(73) Assignee: Hitachi High-Technologies Corporation, Minato-ku, Tokyo (JP)

(21) Appl. No.: 14/397,475

(22) PCT Filed: Apr. 4, 2013
(86) PCT No.: PCT/JP2013/060387

§ 371 Date: Oct. 27, 2014

(30) Foreign Application Priority Data
Apr. 27, 2012 (JP) 2012-102783

(51) Int. Cl. H01J 37/28

(52) U.S. Cl. CPC H01J 37/28; H01J 2237/1504; H01J 2237/216
USPC 348/80

(57) ABSTRACT

A charged particle beam adjustment assistance device that can assist work to adjust a charged particle beam apparatus having a three-dimensional observing function and reduce human labor and man-hours required for adjustment value inputting is provided.

An adjustment value acquiring unit generates optimal three-dimensional adjustment value information on the basis of two-dimensional adjustment value information and two/three-dimensional adjustment value correspondence information generated according to information inputted from a charged particle beam adjuster terminal, transmits the three-dimensional adjustment value information to the charged particle beam apparatus, and sets the three-dimensional adjustment value information therein. Therefore, the charged particle beam adjuster can reduce adjusting work required for three-dimensional observation and facilitate the work of observing three-dimensional images.

### BACKGROUND

The present invention relates to an image displaying apparatus provided with a function to incline charged particle beams, and more particularly to an adjusting method for a charged particle optical system during inclined scanning and during uninclined scanning.

When a three-dimensional image is to be acquired with an charged particle beam apparatus, typically a scanning electron microscope, two images acquired in angularly different directions including an image for the left eye and another image for the right eye are used, and three-dimensional observation is done by a crossing method, a parallel method or an anaglyphic method using red and blue spectacles.

Also, a method by which inclined images of a sample are obtained by inclining charged particle beams leftward and rightward relative to the sample has been devised. As cases of prior art by which images differing in angle are acquired by inclining charged particle beams, Japanese Unexamined Utility Model (Registration) Application Publication No. Sho 55-48610 (Patent Literature 1) and Japanese Unexamined Patent Application Publication No. Hei 2-33843 (Patent Literature 2) are known. These pieces of literature disclose methods by which charged particle beams are brought to incidence off the axis of the object lens and the charged particle beams are inclined by utilizing the focusing action of the object.

Japanese Unexamined Patent Application Publication No. 2011-40240 (Patent Literature 3) discloses a method of providing acquiring means by which a charged particle beam apparatus acquires left and right parallax images not only from above but also in an oblique direction and parallax image displaying means and a method of providing an operation screen that allow change-over of a three-dimensional observation method.

### CITATION LIST

### Patent Literature

Patent Literature 1: Japanese Unexamined Utility Model (Registration) Application Publication No. Sho 55-48610

Patent Literature 2: Japanese Unexamined Patent Application Publication No. Hei 2-33843

Patent Literature 3: Japanese Unexamined Patent Application Publication No. 2011-40240

### SUMMARY

In recent years, a manner of use became applicable in which leftward and rightward inclined images and their synthesized images (anaglyphic images) can be displayed on an operation terminal of a charged particle beam apparatus for acquired images while displaying an uninclined image. The uninclined image, though not directly used for three-dimensional observation, can help obtain the image of the best resolution, and therefore can be used as a model in acquiring leftward and rightward.

Now, when both the uninclined image and inclined images are to be used, it is necessary to make such adjustments for each of these images as astigmatic adjustment, focusing and alignment of irradiation of the observation object surface with charged particle beams to obtain the uninclined image, leftward inclined images and rightward inclined images.

For this reason, the user of an electron microscope conducting observation has to make adjustment first for the uninclined image and next for the leftward and rightward inclined images, entailing a problem of needing an extra workload before starting three-dimensional observation.

For this problem, a method of figuring out the amperage of the inclination control coil of the electron microscope optical lenses from the parallax angle for realizing a three-dimensional view is disclosed in Patent Literature 3, but no means of assisting the user of the electron microscope is provided regarding astigmatic adjustment, focusing or irradiation alignment, which are needed adjustments dependent on the surface unevenness of the three-dimensional image and the space between the observer's left and right eyes. Therefore, in the current situation, adjustment for three-dimensional viewing requires much human labor and many man-hours.

An object of the present invention, intended to solve the problem noted above, is to provide a charged particle beam adjustment assistance device and method that can assist three-dimensional observation with a charged particle beam apparatus and thereby reduce human labor and man-hours required for the adjustment.

To achieve the object stated above, a charged particle beam adjustment assistance device assisting adjustment of a charged particle beam apparatus that performs three-dimensional displaying includes adjustment value correspondence calculation unit (for instance an adjustment value correspondence calculating unit 13) for inputting, from an adjuster's terminal, two-dimensional adjustment values and three-dimensional adjustment values in the charged particle beam apparatus, associates the two-dimensional adjustment value with the three-dimensional adjustment value to generate two/three-dimensional adjustment value correspondence information and stores it into a memory device, and adjustment value acquiring means (for instance an adjustment value acquiring unit 14) for searching, on the basis of the two-dimensional adjustment value, the two/three-dimensional adjustment value correspondence information stored in the memory device for resembling two-dimensional adjustment values and acquires corresponding three-dimensional adjustment values.

According to the present invention, three-dimensional observation in a charged particle beam apparatus can be assisted, and human labor and man-hours required for its adjustment can be reduced.

### BRIEF DESCRIPTION OF THE DRAWINGS

FIG. 1 is a diagram showing an example of functional block configuration of a charged particle beam adjustment assistance device in an embodiment of the present invention.

FIG. 2 is a diagram showing an example of two-dimensional adjustment screen.

FIG. 3 is a diagram showing an example of three-dimensional adjustment screen.

FIG. 4 is a diagram showing examples of data structures of two-dimensional adjustment value information, three-dimensional adjustment value information and two/three-dimensional adjustment value correspondence information.

FIG. 5 is a chart showing an example of detection of the end of a processing flow of three-dimensional adjustment.

FIG. 6 is a chart showing an example of a processing flow of detection of the end of each step of processing of three-dimensional adjustment.

### DESCRIPTION OF THE PREFERRED EMBODIMENTS

Embodiments of the present invention will be described in detail below with reference to drawings.

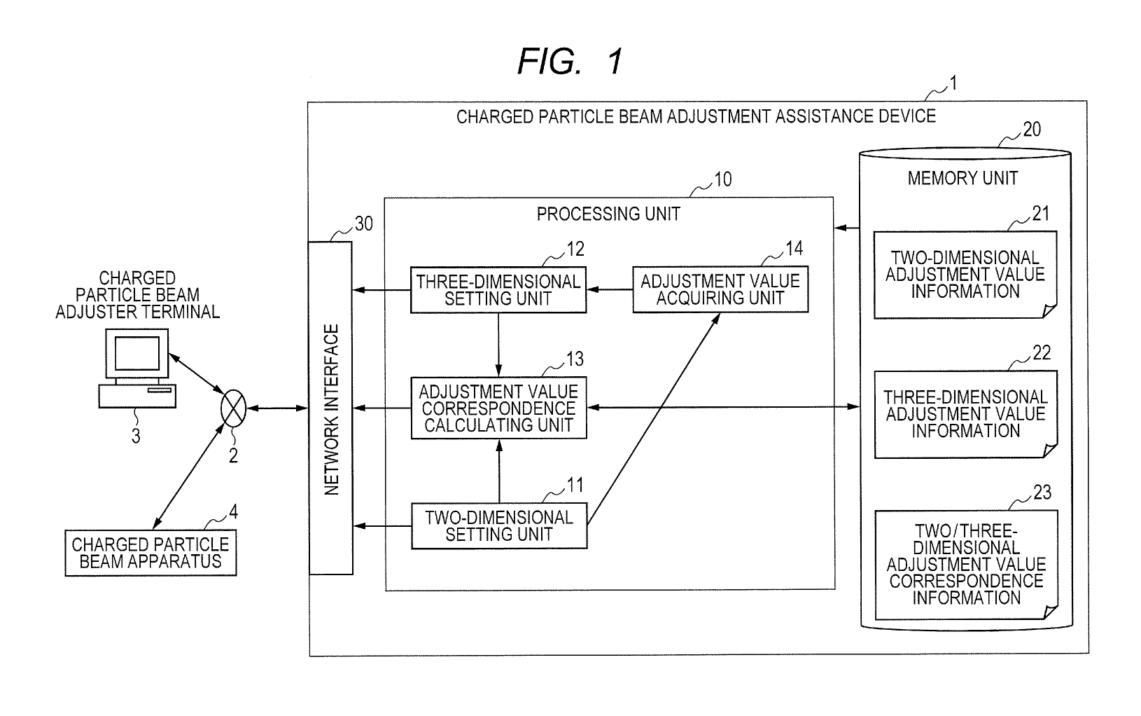

FIG. 1 is a diagram showing an example of configuration of a charged particle beam adjustment assistance device pertaining to an embodiment of the present invention. As shown in FIG. 1, a charged particle beam adjustment assistance device 1 is provided with a processing unit 10, a memory unit 20 and a network interface 30.

The processing unit 10 is configured including, as its functional blocks, a two-dimensional setting unit 11, a three-dimensional setting unit 12, an adjustment value correspondence calculating unit 13 and an adjustment value acquiring unit 14. The memory unit 20 stores two-dimensional adjustment value information 21, three-dimensional adjustment value information 22 and two/three-dimensional adjustment value correspondence information 23 which is the information about the correspondence between the three-dimensional adjustment value and the two-dimensional adjustment value.

The processing unit 10 integrally controls individual constituent elements (for instance a communication unit (not shown)) and processes various arithmetic operations by executing programs stored in the memory unit 20. More specifically, the function of the processing unit 10 is executed by a CPU (Central Processing Unit). The memory unit 20, used for permanent storage of programs and data, is configured of a hard disk, which is a large capacity magnetic memory. The network interface 30 is an interface for exchanging data via a network 2.

As described above, in a charged particle beam adjustment assistance device 1 configured of a computer, the functions of the functional blocks shown in FIG. 1 are realized by the processing unit 10 by executing prescribed programs corresponding to the respective functional blocks stored in the memory unit 20. Therefore, the main operation of the functional blocks of the charged particle beam adjustment assistance device 1 is performed by the processing unit 10. To add, though the grammatical subject of description of an individual functional block should be the processing unit 10 in such a case, description of any individual functional block in this document uses the name of that particular functional block as the grammatical subject.

Further, as shown in FIG. 1, the charged particle beam adjustment assistance device 1 is connected by the network interface 30 to the network 2, and further connected via that network 2 to a plurality of charged particle beam adjuster's terminal 3 to be used by a charged particle beam adjusting person. In such a case, the charged particle beam adjuster's terminal 3 is usually configured of a computer provided with a CPU and a memory unit, and functionally it is used as a display unit or an input/output unit of the charged particle beam adjustment assistance device 1. Incidentally in the following description, the charged particle beam adjuster's terminal 3 will be abbreviated to the adjuster's terminal 3 and the charged particle beam adjusting person to the adjuster.

To add, regarding this embodiment, when an individual block of the charged particle beam adjustment assistance device 1 inputs (acquires) information from an adjuster's terminal 3 via the network interface 30 and the network 2 or outputs (displays) information to the adjuster's terminal 3 via the network interface 30 and the network 2, it will be stated simply that information is inputted (acquired) from the adjuster's terminal 3 or outputs (displays) information to the adjuster's terminal 3.

To add, though the charged particle beam adjustment assistance device 1 is configured of a single computer in the exemplary functional block configuration shown in FIG. 1, the charged particle beam adjustment assistance device 1 may as well be configured of a plurality of computers mutually connected by the network 2 and the like. For instance, the three-dimensional setting unit 12 and the adjustment value correspondence calculating unit 13 may be realized on one each of mutually different computers. Further, where the adjuster's terminal 3 is configured of a computer, the function of the three-dimensional setting unit 12 may as well be realized on the adjuster's terminal 3.

Next, the functions of individual functional blocks in the charged particle beam adjustment assistance device 1 will be outlined with reference to FIG. 1.

The two-dimensional setting unit 11 is a functional block that assists adjustment of an uninclined charged particle beam of a charged particle beam apparatus 4 by the charged particle beam adjuster. The two-dimensional setting unit 11 displays a prescribed two-dimensional adjustment screen on the adjuster's terminal 3, generates the two-dimensional adjustment value information 21 on the basis of adjustment information concerning two-dimensional observation inputted via that two-dimensional adjustment screen and stores it into the memory unit 20. At the same time, it transmits the two-dimensional adjustment value information 21 to the charged particle beam apparatus 4.

The three-dimensional setting unit 12 is a functional block that assists adjustment of leftward and rightward inclined charged particle beams of the charged particle beam apparatus 4 by the charged particle beam adjuster. The three-dimensional setting unit 12 displays a prescribed three-dimensional adjustment screen on the adjuster's terminal 3, generates the three-dimensional adjustment value information 22 on the basis of adjustment information concerning three-dimensional observation inputted via that three-dimensional adjustment screen, and stores it into the memory unit 20. At the same time, it transmits the three-dimensional adjustment value information 22 to the charged particle beam apparatus 4.

The adjustment value correspondence calculating unit 13 is a functional block that associates the two-dimensional adjustment value information 21 with the three-dimensional adjustment value information 22. Adjustment of the uninclined charged particle beam and adjustment of leftward and rightward inclined charged particle beams are accomplished sequentially and, when the two-dimensional setting unit 11 has stored the two-dimensional adjustment value information 21 into the memory unit 20 and the three-dimensional setting unit 12 has stored the three-dimensional adjustment value information 22 into the memory unit 20 as a result, the two-dimensional adjustment value information 21 and the three-dimensional adjustment value information 22 are associated with each other to generate the two/three-dimensional adjustment value correspondence information 23, which is stored into the memory unit 20.

The adjustment value acquiring unit 14 is a functional block that acquires three-dimensional adjustment value information 22 corresponding to the two-dimensional adjustment value information from the memory unit 20 on the basis of the two-dimensional adjustment value information 21 acquired from the two-dimensional setting unit 11. It first searches the two-dimensional adjustment value information 21 contained in the two/three-dimensional adjustment value correspondence information 23 stored in the memory unit 20 for a record resembling the two-dimensional adjustment value information 21 acquired from the two-dimensional setting unit 11, and finds three-dimensional adjustment value information 22 corresponding to the two-dimensional adjustment value information 21, which is the search result. Then, it transmits the acquired three-dimensional adjustment value information 22 to the three-dimensional setting unit 12. Finally, the three-dimensional setting unit 12 transmits three-dimensional adjustment value information 21 to the charged particle beam apparatus 4.

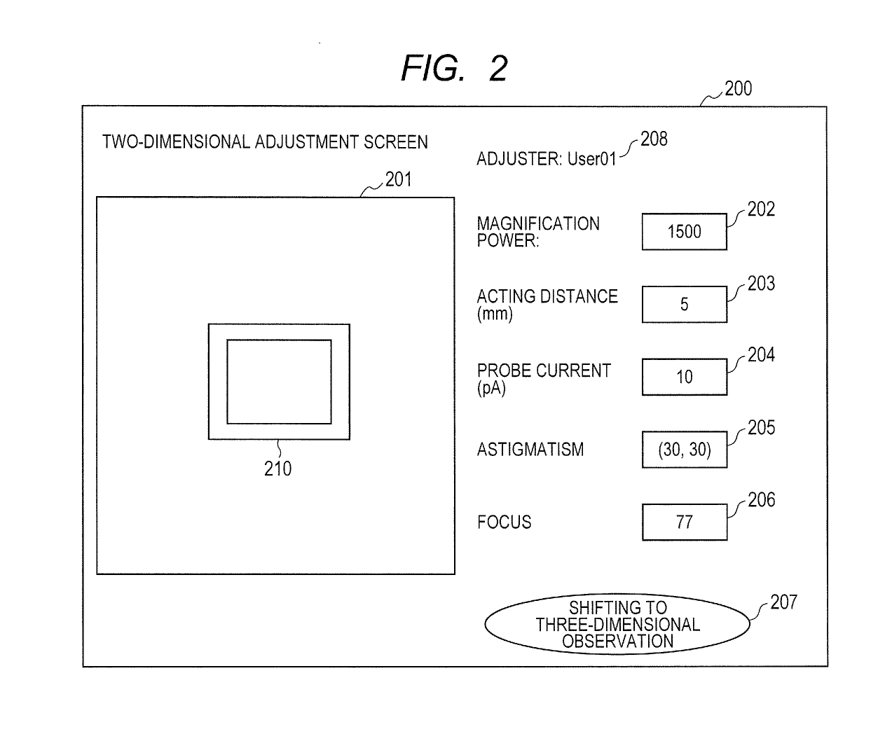

Then, details of the functions of the individual functional blocks of the charged particle beam adjustment assistance device 1 will be described with reference to FIG. 2 and ensuing drawings.

The functions of individual functional blocks work in combination with one another to serve the following two purposes: (1) storing the two-dimensional adjustment value information 21, three-dimensional adjustment value information 22 and two/three-dimensional adjustment value corresponding information 23 into the memory unit 20; and (2) acquisition of the three-dimensional adjustment value information 22 by utilizing the two/three-dimensional adjustment value correspondence information 23.

### <Storage of Various Items of Information 21 to 23>

First, the description will focus on (1).

FIG. 2 is a diagram showing an example of two-dimensional adjustment screen. A two-dimensional adjustment screen 200 shown in FIG. 2 is displayed by the two-dimensional setting unit 11. The two-dimensional adjustment screen 200 is an input screen having a prescribed GUI, and the two-dimensional setting unit 11 displays the two-dimensional adjustment screen 200 on the adjuster's terminal 3.

As shown in FIG. 2, the two-dimensional adjustment screen 200 is configured of a two-dimensional image display area 201 in which an acquired image 210 of the charged particle beam apparatus 4 is displayed, a numerical value input area into which the adjuster is to input adjusted values of [ [symbol] 1] a magnification power 202, an acting distance 203, a probe current 204, an astigmatism 205 and a focus 206, an area 208 for displaying the identifying name of the adjuster, and a button 207 for shifting to three-dimensional observation. The “astigmatism” 205 corresponds to astigmatism aberration in an optical system.

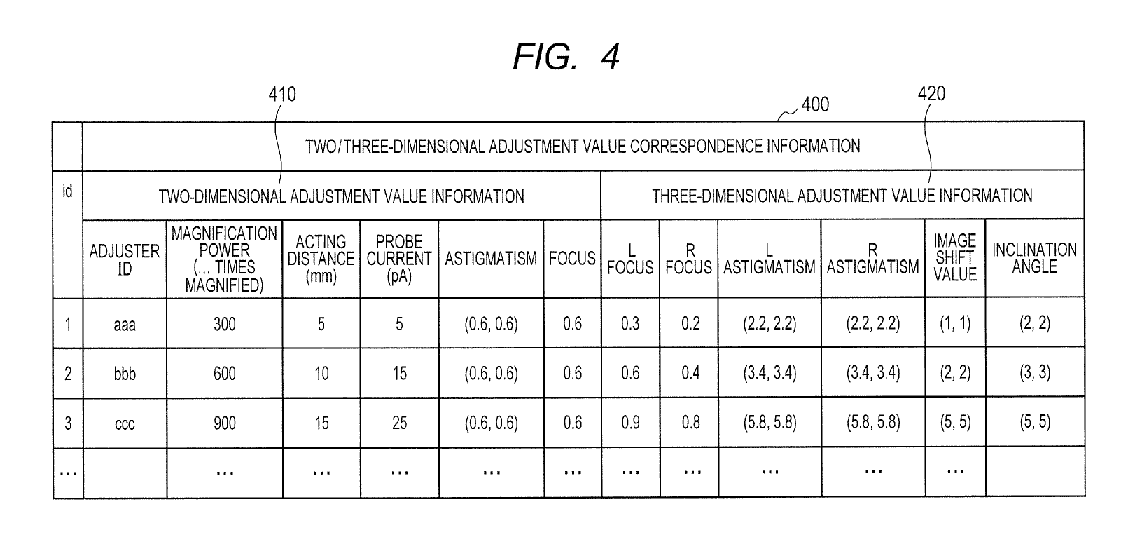

When the adjuster inputs or alters any of the numerical values in the numerical value input area, the two-dimensional setting unit 11 generates the two-dimensional adjustment value information 21 from the inputted value (see 410 in FIG. 4), and transmits it to the charged particle beam apparatus 4 through the network interface 30. The transmitted information is used in setting the charged particle beam apparatus 4 and, as a result, an image acquired from the charged particle beam apparatus 4 after the adjustment value alteration is displayed in the two-dimensional image display area 201.

The identifying name 208 of the adjuster is an identifying name inputted separately from the adjuster terminal by the adjuster at the time of starting the use of the charged particle beam adjustment assistance device 1. This identifying name is held by the processing unit 10, and functional blocks including the two-dimensional setting unit 11 use it for identifying the adjuster.

Upon completing two-dimensional adjustment, the adjuster makes necessary adjustments for three-dimensional observation. Shifting to three-dimensional adjustment is executed by the adjuster's pressing of the three-dimensional observation button 207. In this process, when the adjuster presses the three-dimensional observation button 207, simultaneously the two-dimensional setting unit 11 transmits the current two-dimensional adjustment value information 21 to the memory unit 20, and the memory unit 20 stores it.

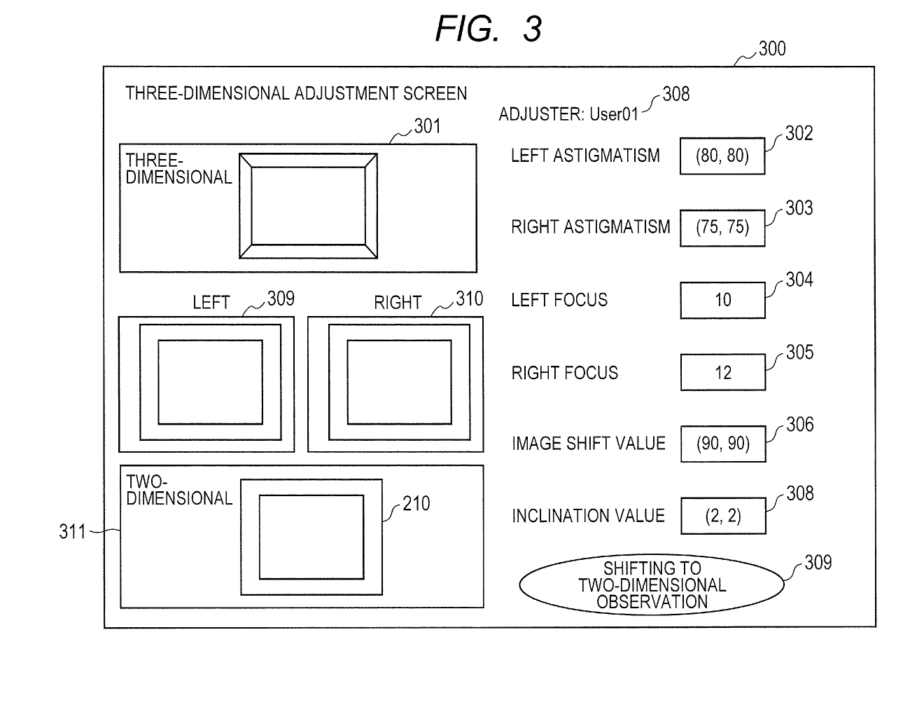

FIG. 3 is a diagram showing an example of three-dimensional adjustment screen. The three-dimensional adjustment screen 300 shown in FIG. 3 is displayed by the three-dimensional setting unit 12. The three-dimensional setting unit 12 is an input screen having a prescribed GUI, and the three-dimensional setting unit 12 displays the three-dimensional adjustment screen 300 on the adjuster's terminal 3.

As shown in FIG. 3, the three-dimensional adjustment screen 300 is configured of a three-dimensional image display area 301 in which a three-dimensional anaglyphic image resulting from synthesis of the leftward and rightward inclined images of the charged particle beam apparatus 4 is displayed, an area 309 in which the leftward inclined image is displayed, an area 310 in which the rightward inclined image is displayed, an area 311 in which the uninclined image acquired from the two-dimensional adjustment screen 200 of FIG. 2 (the acquired image 210) is displayed, an area into which the adjuster is to numerically input adjustment values including astigmatisms (302 and 303) regarding leftward and rightward inclined images, focuses (304 and 305) regarding leftward and rightward inclined images and an image shift 306 indicating the interval between positions on the observation object where leftward and rightward inclined images on the observation object are to be acquired (the distance between the two crossing points between the leftward and rightward view lines and the observation object), a component 308 displaying the identifying name of the user, and a button 309 for shifting to two-dimensional adjustment.

When the adjuster inputs or alters any of the numerical values in the numerical value input area, the three-dimensional setting unit 12 generates the three-dimensional adjustment value information 22 from the inputted value (see 420 in FIG. 4), and transmits it to the charged particle beam apparatus 4 through the network interface 30. The transmitted information is used in setting the charged particle beam apparatus 4 and, as a result, an image acquired after the adjustment value alteration is displayed in the three-dimensional image display area 301. The adjuster now adjusts the stereoscopic effect of the three-dimensional anaglyphic image by altering adjustment values while referencing the uninclined image in the area 311 as a model.

The three-dimensional setting unit 12, upon detecting the end of adjustment by the adjuster, transmits the current three-dimensional adjustment value information 22 to the adjustment value correspondence calculating unit 13. The end of adjustment by the adjuster is detected in the following procedure.

In adjusting the charged particle beam apparatus 4, the adjuster typically carrying out the following procedure.

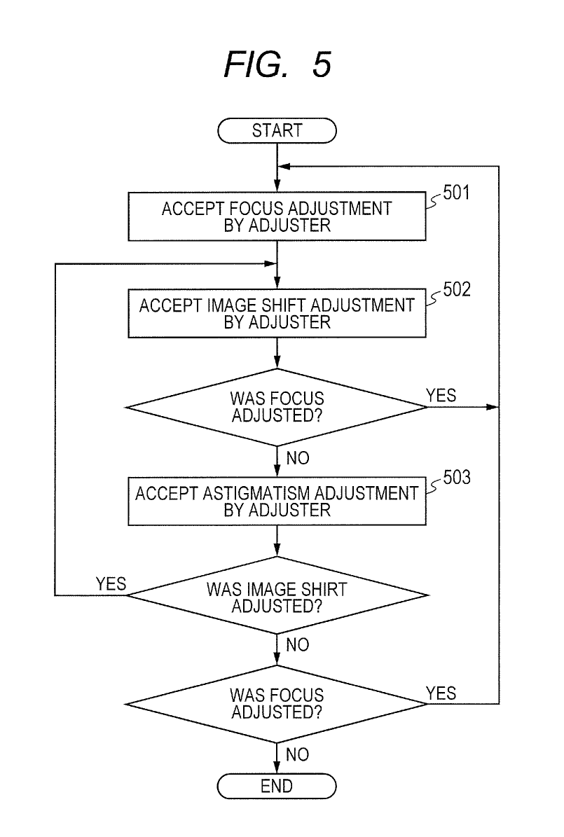

First the adjuster so adjusts the focuses (304 and 305) as to make the leftward and rightward inclined images recognizable, then adjusts the image shift 306 for three-dimensional depth adjustment, and finally adjusts the astigmatisms (302 and 303). Therefore, the three-dimensional setting unit 12 has only to detect that the adjustment has been made on left and right focuses 501, an image shift 502 and left and right astigmatisms 503 as shown in FIG. 5. Or if focus adjustment is done during image shift adjustment 502, it is judged that the adjustment procedure has returned to the previous stage, and a return to acceptance of focus adjustment 501 takes place. Similarly, if focus or image shift adjustment is done during astigmatic adjustment 503, a return to acceptance of focus adjustment 501 or image shift adjustment 502, respectively, takes place. To add, this adjustment sequence is a typical one, and adjustment can as well be done in some other sequence.

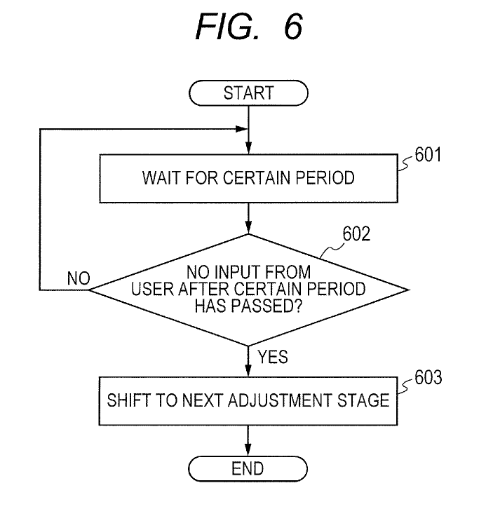

The three-dimensional setting unit 12 detects completion of each step of adjustment. A decision to end acceptance of each step of adjustment is made, as shown in FIG. 6, first after waiting for a certain period to give the adjuster some time to consider (601), and next another certain period to see if the adjuster has given any input to an adjustment value (for instance, the adjustment value for astigmatism) (602). If there has been any input, it is determined that adjustment is continued, and the processing returns to waiting for a certain period (601). If no input is detected for the certain period, the processing shifts to the next stage of adjustment (603).

<Preparation of correspondence information>

The adjustment value correspondence calculating unit 13 receives the three-dimensional adjustment value information 22 transmitted from the three-dimensional setting unit 12, and generates the two/three-dimensional adjustment value correspondence information 23 (400 in FIG. 4). First the adjustment value correspondence calculating unit 13 receives, from the memory unit 20, all records of each of the two-dimensional adjustment value information 21 and the two/three-dimensional adjustment value correspondence information 23. To add, the records of the two/three-dimensional adjustment value correspondence information 23 are in the form of 400 in FIG. 4, having a structure in which two-dimensional adjustment value information records 410 and three-dimensional adjustment value information are associated with each other to have the two sets of information in combination.

In the two-dimensional adjustment value information 21, with records containing no same two-dimensional adjustment value information 21 in any of the records of the two/three-dimensional adjustment value correspondence information 23, the adjustment value correspondence calculating unit 13 associates the three-dimensional adjustment value information 22 received from the three-dimensional setting unit 12 and holds at present to generate the two/three-dimensional adjustment value correspondence information 23 and stores it into the memory unit 20.

So far, (1) it is described focused on storing the two-dimensional adjustment value information 21, the three-dimensional adjustment value information 22 and the two/three-dimensional adjustment value correspondence information 23 into the memory unit 20. Until this point, the adjuster has inputted adjustment values wholly manually by using functional blocks including the two-dimensional setting unit 11 and the three-dimensional setting unit 12.

### <Acquisition of Three-Dimensional Adjustment Value Information 22>

From here onward, (2) the functions of functional blocks will be described with focus on the acquisition of the three-dimensional adjustment value information 22 by utilizing the two/three-dimensional adjustment value correspondence information 23. By acquiring the two/three-dimensional adjustment value correspondence information 23 for the acquisition from the memory unit 20, the three-dimensional setting unit 12 is enabled to acquire three-dimensional adjustment value information 22, semi-automatically accomplish three-dimensional adjustment and assistance of the adjuster.

When the adjuster has completed two-dimensional adjustment and is to carry out three-dimensional adjustment, shifting to the three-dimensional adjustment is accomplished by the adjuster's pressing of the three-dimensional observation button 207. Simultaneously with the pressing of the button 207 by the adjuster, the two-dimensional setting unit 11 transmits the current two-dimensional adjustment value information 21 to the memory unit 20, and the memory unit 20 stores it.

Usually, this is followed by manual three-dimensional adjustment by the adjuster as described so far. However, if the two/three-dimensional adjustment value correspondence information 23 is stored or accumulated in the memory unit 20, three-dimensional adjustment value correspondence information 22 is generated from this stored or accumulated information and transmitted to the charged particle beam apparatus 4.

More specifically, the following actions are taken.

When the adjuster presses the three-dimensional observation button 207, the two-dimensional setting unit 11 transmits the two-dimensional adjustment value information 21 to the adjustment value acquiring unit 14. The adjustment value acquiring unit 14, using the received two-dimensional adjustment value 21 as the key, searches for records of the two/three-dimensional adjustment value correspondence information 23 containing two-dimensional adjustment value information 21 resembling the key, and transmits three-dimensional adjustment value information 22 contained in the information to the three-dimensional setting unit 12 (the method of acquiring the resembling records will be described in detail afterwards). The three-dimensional setting unit 12 transmits the received three-dimensional adjustment value information 22 to the charged particle beam apparatus 4 via the network interface 30.

Hereupon, the method of finding the two/three-dimensional adjustment value correspondence information 23 on the basis of acquisition records resembling the two-dimensional adjustment value information 21 will be described in detail.

In the charged particle beam apparatus 4, there are correlations between each pair of the following combinations of a two-dimensional adjustment value and a three-dimensional adjustment value. More specifically, they are the relations between the adjustment value 204 of the probe current of a two-dimensional adjustment value and the adjustment value 306 of the image shift of a three-dimensional adjustment value, between the adjustment value 203 of the acting distance of a two-dimensional adjustment value and the adjustment value 306 of the image shift of a three-dimensional adjustment value, between the adjustment value 205 of the astigmatism of a two-dimensional adjustment value and the adjustment values 302 and 303 of the left and right astigmatisms of a three-dimensional adjustment value, and between the adjustment value 206 of the focus of a two-dimensional adjustment value and the adjustment values 304 and 305 of the left and right focuses of a three-dimensional adjustment value.

### <Determination of Image Shift Value 306>

Three-dimensional adjustment values are figured out by utilizing the correlation between the two-dimensional adjustment value and the three-dimensional adjustment value. For instance, to determine the image shift value 306 of a three-dimensional adjustment value, the following procedure is performed.

First, the two/three-dimensional adjustment value correspondence information 23 containing the two-dimensional adjustment value information 21 having the closest resemblance to the present probe current and acting distance is figured out. In this process, the following distance definition is used as the criterion of resemblance. The two/three-dimensional adjustment value correspondence information 23 whose resemblance to the current two-dimensional adjustment value is subject to calculation is represented by x.

Resembling distance of x=K1×|Current probe current−Probe current of x|

+K2×|Current acting distance value−Acting distance value of x|

Herein, K1 and K2 are constants determined as a result of experiments.

Adoption of the image shift value of the two/three-dimensional adjustment value correspondence information 23 that minimizes this resembling distance would mean estimation of the optimal image shift value in past cases.

### <Determination of Image Shift Value 306 Based on Correlation>

Since the inclination angle of the three-dimensional adjustment value (the angle of inclining the charged particle beam for configuring the parallax angle to acquire the leftward and rightward inclined images) is correlated to the image shift value of the three-dimensional adjustment value, setting of the inclination angle may as well be utilized on an auxiliary basis to use the following equation for calculation of resemblance.

Resembling distance of x=K1×|Current probe current−Adjustment value of probe current of x|

+K2×|Adjustment value of current acting distance−Adjustment value of acting distance x|

+K3×|Adjustment value of current inclination angle−Adjustment value of inclination angle of x|

Herein, K1, K2 and K3 are constants determined as a result of experiments.

Two/three-dimensional adjustment value correspondence information 23 containing the two-dimensional adjustment value information 21 whose resembling distance is the smallest is figured out, and the image shift value therein is used as the adjustment value.

### <Estimation of Adjustment Values of Astigmatism and of Focus>

In the same way, in estimating the adjusting value of the astigmatism and focus on the basis of correlation between the two-dimensional adjustment values and the three-dimensional adjustment value, it is possible to estimate three-dimensional left and right adjustment values from past two-dimensional adjustment values.

Resemblance regarding the astigmatism is figured out by the following equation.

Resembling distance of x=|Adjustment value of current astigmatism−Adjustment value of astigmatism of x|

In addition, the adjustment value of an astigmatism can be expressed in a pair of x coordinate value and y coordinate value as (x and y), and the value of the difference between the pairs can be represented by the sum of the differences between the x coordinate values and the y coordinate values.

Similarly, resemblance regarding the focus is figured out by the following equation.

Resembling distance of x=|Adjustment value of current focus−Adjustment value of focus of x|

For each, the two/three-dimensional adjustment value correspondence information 23 containing the two-dimensional adjustment value information 21 in which the resembling distance is the smallest is figured out, and the adjustment values of left and right focuses and the adjustment values of left and right astigmatisms are used.

In the foregoing way, with the current two-dimensional adjustment values being used as keys, the two/three-dimensional adjustment value correspondence information 23 containing resembling two-dimensional adjustment values is figured out, the three-dimensional adjustment value contained in the three-dimensional adjustment value information 22 is set in the charged particle beam apparatus, and human labor and man-hours required for adjustment by the adjuster are thereby reduced.

Also, by using this invention, the adjuster can manually make adjustments even after the three-dimensional adjustment value has been set and, by further storing that two/three-dimensional adjustment value correspondence information 23 into the memory unit 20, the adjuster is enabled to estimate the three-dimensional adjustment value more accurately to save his or her trouble of adjustment even more.

### Alternative Embodiment 1

According to the foregoing procedure, the two/three-dimensional adjustment value correspondence information 23 whose resembling distance is the smallest is chosen and the three-dimensional adjustment value contained therein is used, but there also is a conceivable method by which the adjuster sorts items of the two/three-dimensional adjustment value correspondence information 23 in the decreasing order of the resembling distance and chooses one out of a plurality of candidate sets of the smallest resembling distances in the two/three-dimensional adjustment value correspondence information 23. In this case, conceivably an image from each three-dimensional adjustment value candidate is acquired and presented to the adjuster, who chooses the most desirable image and uses its three-dimensional adjustment value.

As this method permits the adjuster to make choice out of a plurality of candidates, it has the advantage of enhancing the probability for the adjuster to obtain the adjustment value best meeting his or her needs.

### Alternative Embodiment 2

In the foregoing description, a method by three-dimensional adjustment values are set one by one is taken up, but a method by which all the attributes of the records of three-dimensional adjustment values are determined at a time is also conceivable.

More specifically, one of the two-dimensional adjustment values is taken note of. For instance, the magnification power of the current two-dimensional adjustment value is noted and, by using it as the key, the two/three-dimensional adjustment value correspondence information 23 is searched for records closer to one another in magnification power. The three-dimensional adjustment value information 22 on the plurality of higher-ranked candidates is utilized to acquire three-dimensional images. It is a method by which the adjuster chooses the most desirable image and adopts the records of that three-dimensional adjustment value information 22.

This method, as it allows all the attributes of the three-dimensional adjustment values to be reproduced in sets, has the advantage of a higher probability of obtaining good adjustment values when there is close relevance among the three-dimensional adjustment values.

### Alternative Embodiment 3

Whereas the foregoing considers the method of estimating three-dimensional adjustment values from two-dimensional adjustment values, it is also possible to estimate, conversely, two-dimensional adjustment values from three-dimensional adjustment values. This method of estimation can also be realized with the same hardware configuration as the foregoing.

### Alternative Embodiment 4

The foregoing considers methods of estimating adjustment values irrespective of who the adjuster is, but if the adjuster prefers to estimate adjustment values by using only his or her own past information, the adjuster may use only those records having the same adjuster ID as his or her own out of the two/three-dimensional adjustment value correspondence information 23. This method has the advantage of a higher probability of obtaining good adjustment values regarding adjustments whose values are determined dependent on the adjuster.

As hitherto described, in this mode of embodying the present invention, the three-dimensional setting unit 12 acquires the three-dimensional adjustment value information 22 from the two/three-dimensional adjustment value correspondence information 23 generated on the basis of information inputted from the charged particle beam adjuster's terminals 3, transmits it to the charged particle beam apparatus 4 and sets the information.

Therefore, the charged particle beam adjuster is enabled to easily set three-dimensional adjustment values and two-dimensional adjustment values and to accomplish adjustment of charged particle beams in a shorter period of time.

### REFERENCE SIGNS LIST

1: Charged particle beam adjustment assistance device, 2: Network, 3: Charged particle beam adjuster terminal, 10: Processing unit, 11: Two-dimensional setting unit, 12: Three-dimensional setting unit, 13: Adjustment value correspondence calculating unit, 14: Adjustment value acquiring unit, 20: Memory unit, 21: Two-dimensional adjustment value information, 22: Three-dimensional adjustment value information, 23: Two/three-dimensional adjustment value correspondence information, 30: Network interface, 200: Two-dimensional adjustment screen, 300: Three-dimensional adjustment screen, 400: Two/three-dimensional adjustment value correspondence information, 410: Two-dimensional adjustment value information, 420: Three-dimensional adjustment value information

1. A charged particle beam adjustment assistance device that assists adjustment of a charged particle beam apparatus that performs three-dimensional displaying, the charged particle beam adjustment assistance device comprising:
two-dimensional adjustment value setting unit which accepts, from an adjuster terminal, two-dimensional adjustment values in the charged particle beam apparatus and transmits the values to the charged particle beam apparatus;
three-dimensional adjustment value setting unit which accepts, from the adjuster terminal, three-dimensional adjustment values in the charged particle beam apparatus and transmits the values to the charged particle beam apparatus;
adjustment value correspondence calculation unit which associates the two-dimensional adjustment values with the three-dimensional adjustment values to generate two/three-dimensional adjustment value correspondence information and stores the information into a memory device; and
adjustment value acquiring unit which searches, on the basis of the two-dimensional adjustment value, the two/three-dimensional adjustment value correspondence information stored in the memory device for resembling two-dimensional adjustment values and acquires corresponding three-dimensional adjustment values.

2. The charged particle beam adjustment assistance device according to claim 1, further comprising:
optimal irradiating position adjustment value estimating unit which estimates, on the basis of adjustment values of a probe current and adjustment values of an acting distance out of two-dimensional adjustment values of the charged particle beam apparatus, an optimal irradiating position adjustment value of charged particle beams in an observation object at the time of acquisition of leftward and rightward inclined images out of three-dimensional adjustment values;
optimal astigmatism adjustment value estimating unit which estimates, on the basis of adjustment values of an astigmatism out of two-dimensional adjustment values of the charged particle beam apparatus, an optimal astigmatism adjustment value at the time of acquisition of leftward and rightward inclined images out of three-dimensional adjustment values; and
optimal focus adjustment value estimating unit which estimates, on the basis of adjustment values of a focus out of two-dimensional adjustment values of the charged particle beam apparatus, an optimal focus adjustment value at the time of acquisition of leftward and rightward inclined images out of three-dimensional adjustment values.

3. The charged particle beam adjustment assistance device according to claim 1, further comprising:
a unit which uses a plurality of candidates for the three-dimensional adjustment value to acquire an image with the charged particle beam apparatus, displays the image on the adjuster terminal, and causes an adjuster to choose an optimal adjustment value.

4. The charged particle beam adjustment assistance device according to claim 1, further comprising:
two-dimensional adjustment value acquiring unit which searches, on the basis of the three-dimensional adjustment value, the two/three-dimensional adjustment value correspondence information stored in the memory device for resembling three-dimensional adjustment value, and acquires a corresponding two-dimensional adjustment value.

5. A charged particle beam adjustment assistance method for assisting adjustment of a charged particle beam apparatus that performs three-dimensional displaying by using a computer,
wherein the computer accepts, with two-dimensional adjustment value setting unit, two-dimensional adjustment values in the charged particle beam apparatus from an adjuster, and transmits the values to the charged particle beam apparatus;
the computer accepts, with three-dimensional adjustment value setting unit, three-dimensional adjustment values in the charged particle beam apparatus from a designer terminal, and transmits the values to the charged particle beam apparatus;
the computer associates, with adjustment value correspondence calculation unit, the two-dimensional adjustment values with the three-dimensional adjustment values to generate two/three-dimensional adjustment value correspondence information, and stores the information into a memory device; and
the computer searches, with adjustment value acquiring unit and on the basis of the two-dimensional adjustment values, the two/three-dimensional adjustment value correspondence information stored in the memory device for resembling two-dimensional adjustment values, and acquires corresponding three-dimensional adjustment values.

6. The charged particle beam adjustment assistance method according to claim 5,
wherein the computer further estimates, with optimal irradiating position adjustment value estimating unit and on the basis of adjustment values of a probe current and adjustment values of an acting distance out of two-dimensional adjustment values of the charged particle beam apparatus, an optimal irradiating position adjustment value of the optimal focus adjustment value of charged particle beams in an observation object at the time of acquisition of leftward and rightward inclined images out of three-dimensional adjustment values;
the computer further estimates, with optimal astigmatic adjustment value estimating unit and on the basis of adjustment values of an astigmatism out of two-dimensional adjustment values of the charged particle beam apparatus, an optimal astigmatism adjustment value at the time of acquisition of leftward and rightward inclined images out of three-dimensional adjustment values; and
the computer further estimates, with focus optimal adjustment value estimating unit and on the basis of adjustment values of a focus out of two-dimensional adjustment values of the charged particle beam apparatus, an optimal focus adjustment value at the time of acquisition of leftward and rightward inclined images out of three-dimensional adjustment values.

7. The charged particle beam adjustment assistance method according to claim 5,
wherein the computer further acquires, with optimal adjustment value choosing unit and by using a plurality of candidates for the three-dimensional adjustment value, an image with the charged particle beam apparatus, and displays the image on the adjuster terminal to have the adjuster choose an optimal adjustment value.

8. The charged particle beam adjustment assistance method according to claim 5,
wherein the computer further searches, with two-dimensional adjustment value acquiring unit and on the basis of the three-dimensional adjustment value, the two/three-dimensional adjustment value correspondence information memory device stored in the memory device for resembling three-dimensional adjustment values, and acquires a corresponding two-dimensional adjustment value.

9. The charged particle beam adjustment assistance method according to claim 5,
wherein the adjuster sorts items of the two/three-dimensional adjustment value correspondence information in the decreasing order of the resembling distance and makes choice out of a plurality of candidate sets of the smallest resembling distances in the two/three-dimensional adjustment value correspondence information.

10. The charged particle beam adjustment assistance method according to claim 5,
wherein the two-/three-dimensional adjustment value correspondence information is searched for records containing the magnification power of the two-dimensional adjustment value, and a three-dimensional image is acquired by using three-dimensional adjustment value information on the plurality of higher-ranked candidates.

11. The charged particle beam adjustment assistance method according to claim 5,
wherein the two-dimensional adjustment value is estimated from the three-dimensional adjustment value on the basis of the two/three-dimensional adjustment value correspondence information.

12. The charged particle beam adjustment assistance method according to claim 5,
wherein an adjustment value corresponding to the adjuster is determined by searching the two/three-dimensional adjustment value correspondence information on the basis of information regarding the adjuster.

13. A computer-readable memory medium storing a program for executing the charged particle beam adjustment assistance method according to claim 5.
